(19) United States
(12) Patent Application Publication
(10) Pub. No.: US 2012/0000697 A1
(43) Pub. Date: Jan. 5, 2012

(54) PRINTED CIRCUIT BOARD AND METHOD OF MANUFACTURING THE SAME

(75) Inventors: Jung Eun Kang, Gyunggi-do (KR); Seog Moon Choi, Seoul (KR); Sung Keun Park, Gyunggi-do (KR); Chang Hyun Lim, Seoul (KR); Kwang Soo Kim, Gyunggi-do (KR)

(73) Assignee: SAMSUNG ELECTRO-MECHANICS CO., LTD., GYUNGGI-DO (KR)

(21) Appl. No.: 12/954,416

(22) Filed: Nov. 24, 2010

(30) Foreign Application Priority Data
Jul. 1, 2010 (KR) 1020100063511

(51) Int. Cl. H05K 1/03; H05K 3/02; H05K 1/02

(52) U.S. Cl. 174/255; 174/256; 427/98.8

(57) ABSTRACT

Disclosed herein is a printed circuit board, including: a substrate having a cavity formed therein; an anodic oxide layer formed by anodizing the substrate; and a circuit layer formed in the cavity. The printed circuit board is advantageous in that, since a circuit layer is formed in a cavity of a substrate, a circuit layer having a thickness necessary for realizing a high-power semiconductor package can be easily formed, and the difficulty of supplying and demanding the raw material of a thick film plating resist can be overcome. Further, the printed circuit board is advantageous in that electrical shorts occurring at the time of forming a thick circuit layer and electrical shorts generated by the compounds remaining after etching can be prevented, thus improving the electrical reliability and stability of a circuit layer.

### CROSS REFERENCE TO RELATED APPLICATION

This application claims the benefit of Korean Patent Application No. 10-2010-0063511, filed on Jul. 1, 2010, entitled “Printed circuit board and the method of manufacturing thereof”, which is hereby incorporated by reference in its entirety into this application.

### BACKGROUND OF THE INVENTION

1. Technical Field

The present invention relates to a printed circuit board and a method of manufacturing the same.

2. Description of the Related Art

Recently, alongside the rapid advancement of semiconductor technology necessary for signal processing, the development of semiconductor devices has been remarkable. Simultaneously, semiconductor packages, such as SIPs (system in packages), CSPs (chip sized packages), FCPs (flip chip packages) and the like, which are formed by mounting an electronic device, such as a semiconductor device, on a printed circuit board, have been under active development. Recently, with the advance of semiconductor technology, the size of the die has been decreased, so that the size of a package substrate for mounting a semiconductor device has also been decreased, with the result that the area in which a bond pad formed on a substrate to be connected with an electronic device can be realized has also been decreased.

Power devices, for example, silicon-controlled rectifiers (SCRs), power transistors, insulated gate bipolar transistors (IGBTs), metal-oxide semiconductor field-effect transistors (MOSFETs), power rectifiers, power regulators, inverters, converters, and high-power semiconductor chips formed of combinations thereof, are designed such that they are operated at a voltage of 30˜1000 V or at a voltage of more than 1000 V. Since high-power semiconductor chips, unlike low-power semiconductor chips such as logic devices and memory devices, operate at high voltage, they are required to have a high heat dissipation capacity and excellent insulating properties at high pressure.

FIG. 1 is a schematic sectional view showing a conventional high-power semiconductor package 100. The conventional high-power semiconductor package 100 includes: a substrate 140 including a base layer 110, an insulation layer 120 and a circuit layer 130; a high-power semiconductor chip 150a and a low-power semiconductor chip 150b mounted on the circuit layer 130 of the substrate 140; and bonding pads respectively formed in the high-power semiconductor chip 150a and the low-power semiconductor chip 150b and connected with the circuit layer 130 by wires 170. Here, the circuit layer 130 is connected to leads serving as external terminals after the wire bonding process, and then an epoxy molding process is performed, completing the high-power semiconductor package 100. Generally, since a high-power semiconductor package emits a large amount of heat when it operates, a radiation plate 180 is provided on the base layer 110 of the high-power semiconductor package. The radiation plate 180 is generally made of a metal having high thermal conductivity. The radiation plate 180 may be adhered on the base layer 110 by an adhesive layer 185. Therefore, the conventional high-power semiconductor package 100 provided with the radiation plate 180 is problematic in that the base layer 110 is additionally required in order to provide the radiation plate 180, its thickness cannot be easily adjusted because the radiation plate 180 is additionally provided, and its size cannot be easily decreased. Further, the conventional high-power semiconductor package 100 is problematic in that the rapidity and reliability of the processes are deteriorated because the process of attaching the base layer 110 must be performed in addition to the process of mounting a semiconductor chip using a lead frame and a wire bonding process. Further, the conventional high-power semiconductor package 100 is problematic in that the total manufacturing cost thereof is increased because the base layer 180 is provided and the adhesive layer 185 is used. Furthermore, the conventional high-power semiconductor package 100 is problematic in that the desired heat dissipation effect cannot be sufficiently realized because the rate of heat radiation possible using the radiation plate 180 is limited.

In order to solve the above problems, conventionally, a high-power semiconductor package was realized using a printed circuit board, which includes a high thermal conductive insulation layer without a radiation plate, the insulation layer being formed by anodizing, and a circuit layer formed on the insulation layer. Here, the printed circuit board used in the high-power semiconductor package must have a thick circuit pattern in order to resist the high temperature and high pressure of high-power devices. Further, in order to form a thick circuit pattern, a thick film resist is needed. However, there is a problem in that the raw material for the thick film resist is difficult to procure in terms of supply and demand, and the straightness of the wall surface of a circuit is decreased with increasing the thickness of the circuit pattern, thus causing electrical shorts. Further, there is another problem in that, at the time of forming a thick circuit pattern by plating, the adhesion between an aluminum substrate and an oxide insulation film is decreased by stress, and electrical shorts occur between pads because of etched residue.

### SUMMARY OF THE INVENTION

Accordingly, the present invention has been devised to solve the above-mentioned problems, and the present invention provides a printed circuit board which can be used to realize a high-power semiconductor package having electrical reliability and stability by forming a cavity in a substrate to form a thick circuit layer, and a method of manufacturing the same.

An aspect of the present invention provides a printed circuit board, including: a substrate having a cavity formed therein; an anodic oxide layer formed by anodizing the substrate; and a circuit layer formed in the cavity.

Here, the exposed surface of the circuit layer may be flush with one side of the substrate having the cavity formed thereon.

Further, the exposed surface of the circuit layer may protrude from one side of the substrate having the cavity formed thereon. Further, the substrate may be made of aluminum, magnesium, titanium or a combination thereof.

Further, the circuit layer may have a thickness of 300 to 400 μm.

Another aspect of the present invention provides a method of manufacturing a printed circuit board, including: providing a substrate; forming a cavity in the substrate; anodizing the substrate having the cavity formed therein; and forming a circuit layer in the cavity.

Here, the substrate may be made of aluminum, magnesium, titanium or a combination thereof.

Further, the forming of the circuit layer may include: forming a seed layer on the substrate having the cavity formed therein; applying a plating resist on an exposed portion of the substrate excluding a portion thereof in which the cavity is formed; forming a circuit plating layer in the cavity; and removing the plating resist and then selectively etching the seed layer exposed on the substrate.

Further, the forming of the cavity in the substrate may include: applying an etching resist on the substrate; etching the substrate; and removing the etching resist.

Further, in the etching of the substrate, the depth of the cavity may be adjusted by controlling etching time.

Further, the circuit layer may have a thickness of 300 to 400 μm.

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a schematic sectional view showing a conventional high-power semiconductor package;

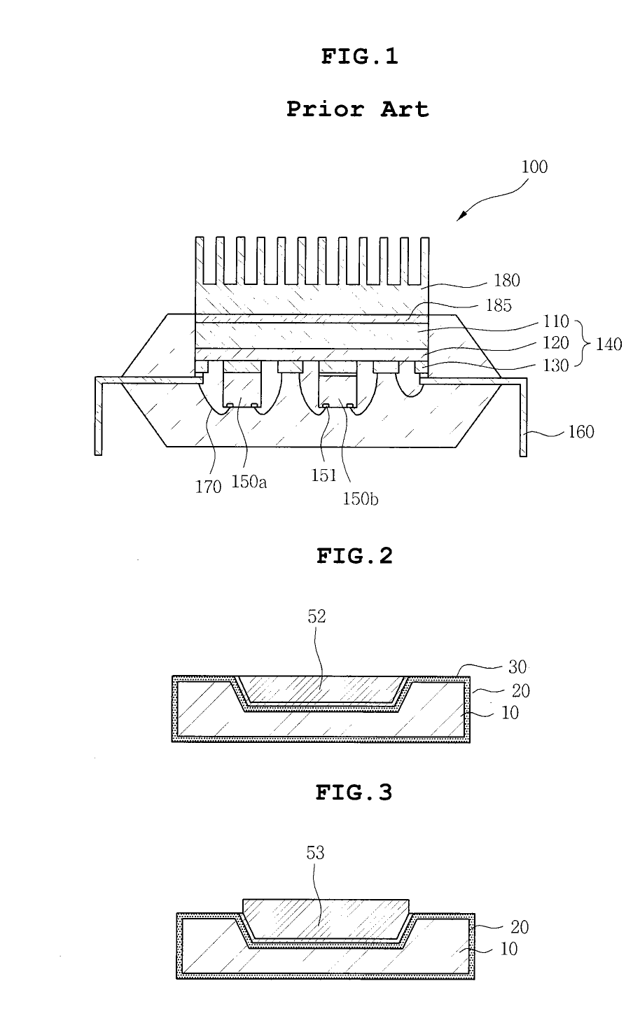

FIG. 2 is a sectional view showing a printed circuit board according to an embodiment of the present invention;

FIG. 3 is a sectional view showing a printed circuit board according to another embodiment of the present invention; and

FIGS. 4 to 12 are sectional views showing a process of manufacturing a printed circuit board according to an embodiment of the present invention.

### DESCRIPTION OF THE PREFERRED EMBODIMENTS

The objects, features and advantages of the present invention will be more clearly understood from the following detailed description of preferred embodiments taken in conjunction with the accompanying drawings. Throughout the accompanying drawings, the same reference numerals are used to designate the same or similar components, and redundant descriptions thereof are omitted. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

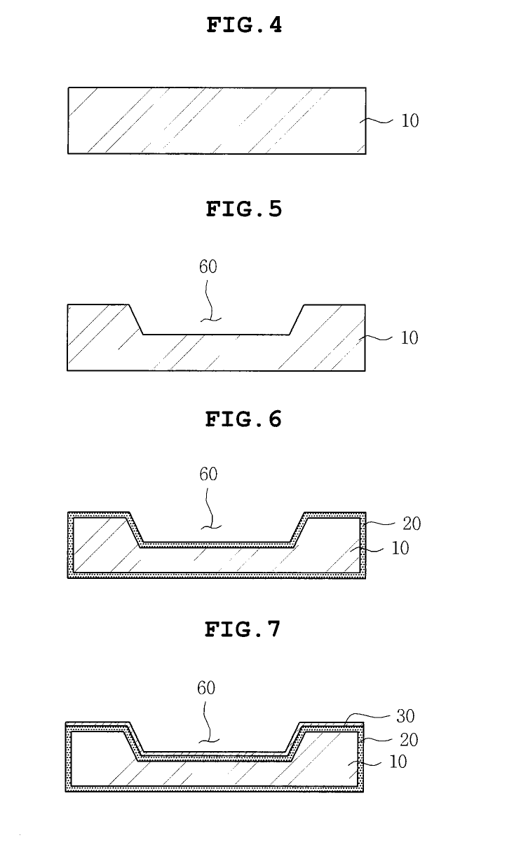

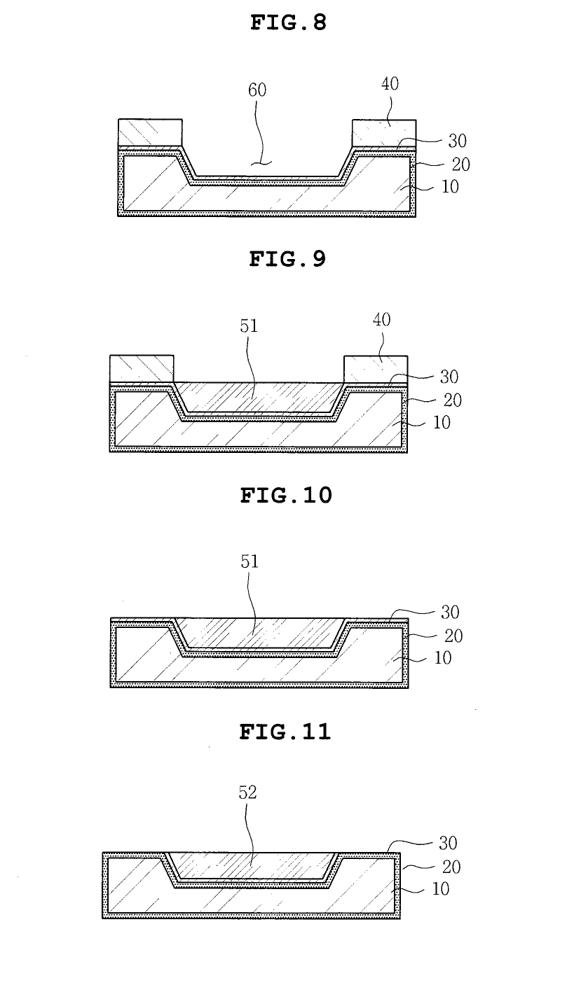

FIG. 2 is a sectional view showing a printed circuit board according to an embodiment of the present invention, and FIG. 3 is a sectional view showing a printed circuit board according to another embodiment of the present invention.

As shown in FIGS. 2 and 3, the printed circuit board according to an embodiment of the present invention includes a substrate 10 having a cavity 60 formed therein, an anodic oxide layer 20 formed by anodizing the substrate 10, and a circuit layer 52 or 53 formed in the cavity 60.

The substrate 10 is made of a material which can be formed into the anodic oxide layer 20 by anodizing, and has a heat radiation effect. The substrate 10 may be made of aluminum, magnesium, titanium or a combination thereof The raw material of the substrate is not particularly limited as long as it can be formed into the anodic oxide layer 20 by anodizing and has heat radiation characteristics. The cavity 60 is formed by etching the substrate 10. The depth of the cavity 60 can be adjusted by controlling the time for etching the substrate 10. A process of etching the substrate 10 to form the cavity 60 will be described later together with a process of manufacturing a printed circuit board.

The anodic oxide layer 20 is formed by anodizing. Concretely, the anodic oxide layer 20 is formed by accelerating the oxidation of the surface of the substrate by allowing the substrate to act as an anode in a specific solution such as a sulfuric acid solution so as to form an oxide film having uniform thickness. Here, the thickness of the anodic oxide layer 20 is determined by the anodizing time and extent, and the substrate 10 is anodized within the range necessary for forming the anodic oxide layer 20 which provides the desired insulation characteristics.

The circuit layer 52 or 53 is formed on the anodic oxide layer 20. The circuit layer 52 or 53 may be formed in various manners such as a subtractive manner, an additive manner and the like. The circuit layer 52 or 53, which is used to realize a high-power semiconductor package, may be thickly formed because it must resist the high temperature and high pressure generated by high-power devices. Conventionally, a thick film resist has been used in order to realize the thick circuit layer 52 or 53, but, in the present invention, the thick circuit layer 52 or 53 can be more easily realized by forming the cavity 60 in the substrate 10 and then forming the circuit layer 52 or 53 in the cavity 60. The circuit layer 52 or 53 formed in the cavity 60 and exposed on the substrate 10 may be formed such that it is flush with one side of the substrate provided with the cavity 60 (refer to FIG. 2) or it protrudes from one side thereof (refer to FIG. 3). The thickness of the circuit layer 52 or 53 may be adjusted by changing the depth of the cavity 60 or by changing the height of a plating resist 40 formed at both ends of the cavity 60. The thickness of the circuit layer 52 or 53 of a printed circuit board for realizing a high-power semiconductor package may be in a range of 300 to 400 μm, but is not limited thereto.

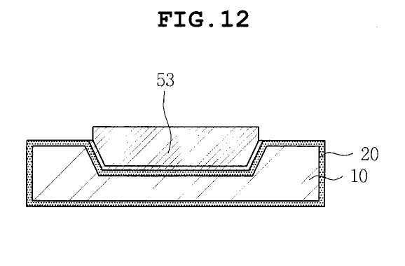

FIGS. 4 to 12 are sectional views showing a process of manufacturing a printed circuit board according to an embodiment of the present invention.

A method of manufacturing a printed circuit board according to an embodiment of the present invention includes the steps of: providing a substrate 10; forming a cavity 60 in the substrate 10; anodizing the substrate provided with the cavity 60; and forming a circuit layer 52 or 53 in the cavity 60.

First, as shown in FIG. 4, a substrate 10 is provided. Here, the substrate 10 is made of a material which can be formed into an anodic oxide layer 20 by anodizing, and has a heat radiation effect. The substrate 10 may be made of aluminum, magnesium, titanium or a combination thereof. The raw material of the substrate is not particularly limited as long as it can be formed into the anodic oxide layer 20 by anodizing and has heat radiation characteristics.

Subsequently, as shown in FIG. 5, a cavity 60 is formed in the substrate 10. In this case, a circuit layer 52 or 53 is formed in the cavity 60 of the substrate 10 to increase the thickness of the circuit layer 52 or 53, thus improving the electrical reliability and stability of the circuit layer 52 or 53 of the printed circuit board to be used in a high-power semiconductor package. The cavity 60 may be formed by etching the substrate 10. The method of forming the cavity 60 is not limited thereto, and the cavity 60 may be formed in various ways such as laser machining and the like. Concretely, the process of etching the substrate 10 includes the steps of: applying an etching resist on the substrate; etching the substrate 10; and removing the etching resist. The depth of the cavity 60 formed in the substrate 10 can be adjusted by controlling the time for etching the substrate 10.

Subsequently, as shown in FIG. 6, the substrate 10 provided with the cavity 60 is anodized. An anodic oxide layer 20 having both insulation properties and heat radiation characteristics can be formed by anodizing the substrate 10. In order to form the anodic oxide layer 20 by anodizing the substrate 10, a metal substrate made of aluminum, magnesium, titanium or a combination thereof may be used as the substrate 10. When anodizing the substrate 10, the oxidation of the surface of a metal substrate is accelerated by allowing the metal substrate to act as an anode in a specific solution such as a sulfuric acid solution, thus forming an oxide film having uniform thickness. Here, the thickness of the anodic oxide layer 20 is determined by the anodizing time and extent, and the substrate 10 may be anodized within the range necessary for forming the anodic oxide layer 20 which provides the desired insulation characteristics.

Subsequently, as shown in FIG. 7, a seed layer 30 is formed on the substrate provided with anodic oxide layer 20 in order to form the circuit layer 52 or 53. The seed layer, which serves as an incoming line for electrolytic plating, may be formed by wet plating (electroless plating) or dry plating (sputtering).

Subsequently, as shown in FIG. 8, a plating resist 40 is applied at both ends of the cavity 60 formed in the substrate 10. Because of the cavity 60, the circuit layer 52 or 53 can be stably formed to a desired thickness without using a thick film plating resist, and the difficulty of supplying and demanding the raw material of the thick film resist can be overcome. In order to form the circuit layer 52 or 53 in the cavity 60, the plating resist 40 may be applied at both ends of the cavity 60, and may be applied in various forms depending on the shape of the cavity 60. Here, since the thickness of the plating resist 40 need not correspond to the thickness of the circuit layer 52 or 53, the circuit layer 52 or 53 can be formed more thickly using plating resist 40 that is thinner than the circuit layer 52 or 53.

Subsequently, as shown in FIG. 9, a circuit plating layer 51 is formed in the cavity 60 after the plating resist 40 has been applied on the substrate 10. Here, one side of the circuit plating layer 51 formed in the cavity 60 and exposed on the substrate 10 may be flush with one side of the substrate 10 provided with the cavity 60 (refer to FIG. 2). Further, one side of the circuit plating layer 51 formed in the cavity 60 and exposed on the substrate 10 may protrude from one side of the substrate 10 provided with the cavity 60, thus forming a circuit layer thicker than the depth of the cavity 60 (refer to FIG. 3).

Subsequently, as shown in FIG. 10, the plating resist 40 is removed after the circuit plating layer 51 has been formed.

Finally, as shown in FIG. 11, a circuit layer 52 or 53 is formed by selectively etching the exposed seed layer 30 remaining on the substrate without forming a circuit pattern, after the plating resist is removed as shown in FIG. 10. Here, the circuit layer 52 is formed by allowing the one side of the circuit plating layer 51 formed in the cavity 60 and exposed on the substrate 10 to be flushed with the one side of the substrate 10 provided with the cavity 60. According to another embodiment, as shown in FIG. 12, the circuit layer 53 is formed by allowing the one side of the circuit plating layer 51 formed in the cavity 60 and exposed on the substrate 10 to protrude from the one side of the substrate 10 provided with the cavity 60. That is, the circuit layer 52 or 53 thicker than the depth of the cavity 60 can be formed using the plating resist 40. Therefore, even this case has the advantage that a thick film plating resist need not be used because a circuit layer is formed in the cavity 60.

As described above, according to the present invention, there is an advantage in that an anodic oxide layer formed by anodizing a metal substrate is used as an insulation layer, thus improving the heat radiation characteristics of a printed circuit board.

Further, there is an advantage in that a circuit layer is formed by forming a cavity in a metal substrate, thus providing a printed circuit board with a thick circuit layer without using a thick film resist.

Further, there is the advantage that the adhesion area of a circuit layer and an anodic oxide layer is increased when the circuit layer is formed, thereby improving the adhesivity between the circuit layer and the anodic oxide layer.

Further, there is an advantage in that the straightness of the wall surface of a circuit is not decreased, thus preventing electrical shorts from occurring between circuit patterns.

Further, there is an advantage in that the electrical short between circuit patterns, attributable to the compounds remaining after etching, can be prevented when the circuit layer is being etched and formed.

Further, there is an advantage in that a circuit layer is formed in a cavity of a metal substrate, thus preventing electrical shorts between pads.

Further, there is an advantage in that a circuit layer is formed thickly, thus realizing a high-power semiconductor package having reliability.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Simple modifications, additions and substitutions of the present invention belong to the scope of the present invention, and the specific scope of the present invention will be clearly defined by the appended claims.

What is claimed is:

1. A printed circuit board, comprising:
a substrate having a cavity formed therein;
an anodic oxide layer formed by anodizing the substrate; and
a circuit layer formed in the cavity.

2. The printed circuit board according to claim 1, wherein an exposed surface of the circuit layer is flush with one side of the substrate having the cavity formed thereon.

3. The printed circuit board according to claim 1, wherein an exposed surface of the circuit layer protrudes from one side of the substrate having the cavity formed thereon.

4. The printed circuit board according to claim 1, wherein the substrate is made of aluminum, magnesium, titanium or a combination thereof.

5. The printed circuit board according to claim 1, wherein the circuit layer has a thickness of 300 to 400 μm.

6. A method of manufacturing a printed circuit board, comprising:
providing a substrate;
forming a cavity in the substrate;
anodizing the substrate having the cavity formed therein; and
forming a circuit layer in the cavity.

7. The method according to claim 6, wherein the substrate is made of aluminum, magnesium, titanium or a combination thereof.

8. The method according to claim 6, wherein the forming of the circuit layer comprises:
forming a seed layer on the substrate having the cavity formed therein;
applying a plating resist on an exposed portion of the substrate excluding a portion thereof in which the cavity is formed;
forming a circuit plating layer in the cavity; and
removing the plating resist and then selectively etching the seed layer exposed on the substrate.

9. The method according to claim 6, wherein the forming of the cavity in the substrate comprises:
applying an etching resist on the substrate;
etching the substrate; and
removing the etching resist.

10. The method according to claim 9, wherein, in the etching of the substrate, the depth of the cavity is adjusted by controlling etching time.

11. The method according to claim 6, wherein the circuit layer has a thickness of 300 to 400 μm.
